(19) United States
(12) Patent Application Publication
(10) Pub. No.: US 2025/0076438 A1
(43) Pub. Date: Mar. 6, 2025

(54) Slice Multiplexing Method

(71) Applicant: Siemens Healthineers AG, Forchheim (DE)

(72) Inventor: Mario Zeller, Erlangen (DE)

(73) Assignee: Siemens Healthineers AG, Forchheim (DE)

(21) Appl. No.: 18/817,761

(22) Filed: Aug. 28, 2024

(30) Foreign Application Priority Data
Aug. 31, 2023 (DE) 10 2023 208 332.9

(51) Int. Cl. G01R 33/561; G01R 33/483; G01R 33/56

(52) U.S. Cl. CPC G01R 33/5611; G01R 33/4835; G01R 33/5608; G01R 33/5615

(57) ABSTRACT

Measurement data of an examination object is recorded as collapsed from a plurality of slices of the examination object simultaneously while using an in-plane acceleration technique with an undersampled sampling pattern of the k-space. The measurement data is separated into single-slice measurement data by recording reference measurement data in at least two segments such that a complete set of reference measurement data is recorded. A sampling pattern is used within a segment during the recording of the reference measurement data that corresponds to an acceleration factor to which the sampling pattern of the collapsed measurement data corresponds. The collapsed measurement data is recorded, and the separation of the data is performed based upon on the reference measurement data recorded in at least one of the at least two segments. The separation of the collapsed measurement data is recorded into single-slice measurement data while using the created separation data.

### CROSS-REFERENCE TO RELATED APPLICATIONS

The present application claims priority to and the benefit of Germany patent application no. DE 10 2023 208 332.9, filed on Aug. 31, 2023, the contents of which are incorporated herein by reference in their entirety.

### TECHNICAL FIELD

The disclosure relates to an improved slice multiplexing method, in particular to an improved slice multiplexing method using an acceleration technique in the plane (in-plane technique).

### BACKGROUND

Magnetic resonance (MR) technology is a known technology with which images from within the inside of an examination object can be generated. Expressed in simple terms, to do this the examination object is positioned in a magnetic resonance device in a comparatively strong static, homogeneous basic magnetic field, also called a B0 field, with field strengths of 0.2 tesla to 7 tesla and more, so that its nuclear spins align along the basic magnetic field. To trigger nuclear spin resonances able to be measured as signals, radio-frequency (RF) excitation pulses are radiated into the examination object, the triggered nuclear spin resonances are measured as so-called k-space data, and MR images of spectroscopy data is determined on the basis of them. For spatial encoding of the measurement data, rapidly switched magnetic gradient fields, known as gradients for short, are overlaid onto the basic magnetic field. A scheme used that describes a temporal sequence of RF pulses to be radiated in and gradients to be switched is referred to as a pulse sequence (scheme), or also just as a sequence for short. The recorded measurement data is digitized and stored as complex numerical values in a k-space matrix. An associated MR image is able to be reconstructed from the k-space matrix, for example by means of a multidimensional Fourier transformation.

In recent years, a speeding up of MR measurements by explicit undersampling of the k-space, by so-called parallel acquisition techniques for example, has become established. The said parallel acquisition techniques (ppa techniques) with the aid of which acquisition times needed for recording the desired data by incomplete sampling, i.e. undersampling of the (2D) k-space in accordance with the Nyquist condition, are able to be shortened, include GRAPPA (“GeneRalized Autocalibrating Partially Parallel Acquisition”) und SENSE (“SENSitivity Encoding”) for example. The measurement points in the k-space not measured within the framework of the undersampling in parallel acquisition techniques are as a rule evenly distributed over the k-space to be measured in accordance with Nyquist condition, so that for example each second k-space row in each k-space plane (kx,ky) assigned to a slice is measured. Such ppa techniques are therefore also referred to as in-plane acceleration techniques.

The “missing” k-space data is reconstructed in parallel acquisition techniques with the aid of coil sensitivity data. This coil sensitivity data of the receive coils used during the recording of the measurement data is determined on the basis of reference measurement data, which samples at least one area of the k-space to be measured, mostly the central area, that is completely in accordance with the Nyquist condition. The coil sensitivity data determined from the reference measurement data for a reconstruction of missing k-space data is also referred to as the “kernel”, in the case of GRAPPA also as the “GRAPPA kernel”.

Any measurement data from which image data is not (or is not only) reconstructed, but which is used as a reference for determination of further information for a technique used or for an algorithm, is referred to here as reference measurement data.

However, these and other types of undersampling schemes have various drawbacks, as further noted herein.

### SUMMARY

One of the fastest known MR recording techniques is what is known as Echo Planar Imaging (EPI) in which, after an RF excitation pulse, an oscillating, i.e. bipolar, readout gradient is employed, which for each change of the polarization direction of the gradient, refocuses the transversal magnetization far enough to allow the T2* relaxation, and thus creates a gradient echo in each case. In other words, through the switching of the bipolar readout gradients after an RF excitation pulse within the free induction decay after the excitation (FID), or if in addition an RF refocusing pulse is radiated in after the RF excitation pulse within the spin echo created in this way, an echo train of rising and falling gradient echoes with alternating leading signs is created. EPI pulse sequences can be employed as a so-called single-shot method, in which all measurement data for creating an image of a sub-volume, for example of a slice, of the object being examined is recorded after only one RF excitation pulse.

Along with a reduction in the measurement duration, depending on the MR imaging technique used, further advantages are produced for parallel acquisition techniques. In EPI recording techniques for example the length of the readout train, e.g. within the framework of functional MR imaging (fMRI), for the determination of diffusion Diffusion-Weighted Imaging (DWI) characteristics or for perfusion measurements are reduced. This enables the echo time of the recorded echo signals to be reduced, which brings with it a higher signal-to-noise-ratio (SNR). Furthermore, a higher bandwidth in the phase encoding direction can be achieved whereby distortions are reduced. What is more, through this type of reduction of the length of the readout train, an influence of the T2* relaxation on the recorded signals can be reduced, whereby sharper images can be obtained.

In routine clinical use, undersampling factors in the range of 2-4 are typically employed—in such cases in-plane undersamplings are typically combined with the simultaneous recording of a number of slices (Simultaneous Multi-Slice (SMS)).

In general, these types of methods, in which images of various slices are recorded simultaneously, are characterized in that, at least during a part of the measurement, transversal magnetization of at least two slices simultaneously is explicitly used for the imaging process (multi-slice imaging, slice multiplexing). By contrast with this, in established multi-slice imaging, the signal from at least two slices is recorded alternately, i.e. completely independently of one another, with a correspondingly longer measurement time.

Known methods of this type, also called Simultaneous Multi-Slice (SMS) methods, are for example the so-called Hadamard encoding, methods with simultaneous echo refocusing, methods with broadband data recording, or also methods that employ a parallel imaging in the slice direction. The last-mentioned methods also include the Controlled Aliasing in Parallel Imaging Results in Higher Acceleration (CAIPIRINHA) technique for example, as is described by Breuer et al. in “CAIPIRINHA for Multi-Slice Imaging”, Magnetic Resonance in Medicine 53, 2005, pp. 684-691, and the blipped CAIPIRINHA technique, as is described by Setsompop et al. in “Blipped-Controlled Aliasing in Parallel Imaging for Simultaneous Multislice Echo Planar Imaging With Reduced g-Factor Penalty”, Magnetic Resonance in Medicine 67, 2012, pp. 1210-1224.

In the last-mentioned slice multiplexing method in particular, a so-called multi-band RF pulse is used to excite two or more slices simultaneously or manipulate them in another way, for example to refocus or saturate them. Such a multi-band RF pulse in this case is a multiplex of individual RF pulses, which would be used for manipulation of the individual slices to be manipulated at the same time. Through the multiplexing, a baseband-modulated multi-band RF pulse is obtained from an addition of the pulse shapes of the individual RF pulses. The spatial encoding of the recorded signals is achieved in this case essentially by a widely-used gradient switching in two directions (two-dimensional gradient encoding).

The signals arising are collapsed from all excited slices in one data set recorded by means of a number of receive antennas and must then be separated according to the individual slices.

The algorithms with which the recorded signals can be separated again and assigned to the individual slices are based on the availability of further information, from which the spatial sensitivity of the receive antennas (sensitivity data) is determined, which is determined as a rule from reference measurement data. Such sensitivity data—as well as the spatial encoding by the gradient fields—is used as additional spatial encoding, with which, via the solution of equation systems, by means of iterative methods or using trained networks, the desired signal assignment is undertaken.

In slice multiplexing methods, parallel acquisition techniques can be used to separate once again the measurement data recorded at the same time and thus collapsed for various slices. In this case, reference measurement data has to be recorded in each case for all slices involved. This occurs as a rule within the framework of an additional reference measurement to be carried out, which measures reference measurement data individually for each desired slice.

To be able to separate the resulting signals of the various slices, the individual RF pulses are each impressed before multiplexing with a different phase. This can be undertaken for example by adding a phase, which increases linearly (for example with the k-space coordinates in the phase encoding direction (ky)). This enables a different phase increase to be impressed on each slice, whereby the slices in the image space are shifted towards each other. This shifting is checked by the so-called FOV (field of view) shift factor. How an optimum FOV shift factor can be determined is described in DE102016218955 for example.

In the CAIPIRINHA method described in the said articles by Breuer et al. and Setsompop et al., by switching of additional gradient blips or by additional modulation of the phases of the RF pulses of the multi-band RF pulses, alternating further phase shifts are impressed between the simultaneously excited slices, which in the slice direction create shifts in the image space (interslice FoV shifts). These additional shifts in the image space improve the quality of the separation of the signals of the slices, for example by means of the slice GRAPPA method mentioned in the article by Breuer et al., in particular when the coil sensitivities have small differences in the sensitivity profiles of the individual coils used such that these are otherwise not sufficient for a reliable separation of the slices. Thus artifacts in the image data ultimately reconstructed from the measured measurement data are reduced. The sensitivity data determined from the reference measurement data for a separation of measurement data recorded collapsed of a number of slices in measurement data of individual slices are also referred to as the kernel, in the case of slice GRAPPA also as the slice GRAPPA kernel.

The effect of the additional phase shifts on the sampling scheme of a two-dimensional (2D) slice multiplexing measurement can be described as follows: Through the additional phases, which are impressed in the slice multiplexing CAIPIRNHA method, the measurement points to which the additional phase is applied are shifted by a shift in the k-space in the kz direction. How large this shift in the kz direction turns out to be depends on the impressed phase. This is also described for example in the article by Zahneisen et al.: “Three-Dimensional Fourier Encoding of Simultaneously Excited Slices: Generalized Acquisition and Reconstruction Framework”, Magn. Reson. Med. 71, pp. 2071-2081 (2014).

The reference measurement data, from which sensitivity data for separation of simultaneously recorded slices is obtained (slice separation reference measurement data), is as a rule measured additionally for each slice multiplexing measurement.

Further to be noted in EPI acquisition techniques is that, on account of the changing polarity of the readout gradients with which the echo signals are recorded as measurement data, even small asymmetries in the measurement data recorded in this way lead to inconsistencies in the k-space data and consequently to undesired replicas (also called (N/2) ghosts) in the image data. These types of asymmetries can for example be the consequence of dynamic interference fields (for example through induced eddy currents during switching of gradient fields).

This occurs since the measurement data obtained from the echo signals recorded by means of EPI are sorted into a raw data k-space matrix in such a way that the sorting-in direction changes from row to row of the raw data k-space matrix. If even only slight deviations are produced here from row to row, for example through delays in the gradient switching or eddy currents, this leads to so called (N/2) ghosts, i.e. with an image matrix of N×N points the actual image is imaged once again shifted by N/2 in the positive and negative direction with regard to the middle of the image, and indeed generally with different intensity. For correction of such (N/2) ghosts, it is known for example from U.S. Pat. No. 6,043,651 to record three navigator signals while switching a bipolar readout gradient, with which a correction of zero-order and first-order phase shifts between gradient echoes recorded with different polarity in the readout direction can be carried out, which can correct these types of shifts. To this end, a correlation of the recorded navigator signals in the image space is used to determine correction factors, which will be used in a reconstruction of image data from the gradient echoes recorded as measurement data in a raw data k-space matrix in order to correct the said shifts in the raw data k-space matrix.

A further phase correction method, called DORK, for correction of shifts caused by temporal variations of a basic magnetic field present during an EPI measurement, for example a drift, in which a navigator signal is recorded, is known for example from U.S. Pat. No. 9,329,254. In this method, an evolution of the gradient echoes that have been recorded with one polarity are compared with an evolution of the gradient echoes that have been recorded with another polarity, over successive recordings of raw data k-space matrices. Usually with such a DORK correction an average is taken over an entire image volume.

As a rule, such known correction methods are successful in reducing asymmetries in the measurement data measured for an imaging, and, providing these are likewise recorded by means of EPI, also in reference measurement data, to the extent that the impression of residual ghosts in their image data (image ghosts) no longer plays any actual role for clinical diagnostics.

However, such correction methods based on one-dimensional navigator signals can reach their limits, e.g. when the interference fields causing inconsistencies have spatial variations not just in the readout direction. Although an intensity of image ghosts is then further reduced, image artifacts possibly still remain however, which can still lead to restrictions in clinical usability.

By means of a Dual Polarity GRAPPA technique (DPG), described for example in the article by Hoge et al, “Dual-Polarity GRAPPA for Simultaneous Reconstruction and Ghost Correction of Echo Planar Imaging Data,” Magn. Reason. Med. 76: pp. 32-44, 2016, the intensity of image ghosts can be successfully reduced, even with complex geometries of the interference fields, to the extent that the images are suitable without restrictions for the clinical diagnosis.

Further reference measurement data is needed for such a DPG approach. In particular, sets of reference measurement data recorded entirely in accordance with Nyquist for each desired slice and both polarization directions are used, from which in each case complete reference measurement data sets are created for each polarization direction, which are used to create coil sensitivity data for both polarization directions, and which are employed in the reconstruction of image data recorded as a rule from measurement data undersampled by means of an EPI recording technique within the framework of the DPG method largely to avoid ghost artifacts, e.g. even under conditions with non-linear phase variations. For example, before the actual DPG algorithm is executed, reference measurement data for a DPG algorithm from two sets of reference measurement data each recorded with inverted polarities of the readout gradients, in each case a sample set of sorted reference measurement data each with only one readout direction, i.e. each with only positive polarity of the readout gradient or each with only negative polarity of the, for example by corresponding assignment of recorded k-space rows, can be combined.

In its original form, an algorithm employed for DPG simultaneously ensures the reduction of image ghosts and the supplementing of k-space data missing because of the GRAPPA technique employed. Modified variants can, however, also only reduce the asymmetries of the measurement data recorded with positive or negative readout gradient in k-space so that a reduction of image ghosts is also possible for fully sampled measurement data for an imaging, for example even an imaging by means of an SMS technique, and/or for alternative reconstruction methods (for example DL-based provision of missing k-space data).

A number of methods for recording the reference measurement data for the application of a DPG algorithm are known. What is common to all methods is that necessarily two sets of reference measurement data, each with inverted polarity of the readout gradient, are recorded.

It is known for example that reference measurement data can be recorded for a DPG algorithm by means of a single-shot EPI recording technique in which, for each slice in which measurement data is recorded for an imaging, after one excitation in each case, reference measurement data is recorded by means of an EPI recording technique. Here, the contrast of the reference measurement data can deviate from a respective of the measurement data recorded for the imaging because for example, for the recording of the reference measurement data, a shorter repetition time TR has been chosen than for the recording of the measurement data for the imaging, in order to reduce the duration of the measurement time needed for the recording of the reference measurement data. In a second measurement reference measurement data is recorded with inverted readout gradients.

It is further known that reference measurement data for DPG algorithms can be recorded by means of a multi-shot EPI recording technique, in which the reference measurement data of each slice for which measurement data is to be recorded for an imaging is recorded with a number of excitations of a segmented EPI recording technique. Here, too, the contrast of the reference measurement data can deviate from a respective contrast of the measurement data recorded for the imaging, for example when a shorter repetition time TR is chosen for the recording of the reference measurement data in order to reduce the overall measurement time. Once again, reference measurement data is recorded with inverted readout gradients in second measurements.

For the recording of reference measurement data for a DPG algorithm with a multi-shot EPI recording technique, a conventional segmentation can be used in which the k-space to be recorded is divided into segments, from which, after an excitation in each case, reference measurement data is recorded. In this case, the reference measurement data of the individual segments is recorded in each case after a longer relaxation time with a relatively large time interval thereby between the individual excitations, but with an identical flip angle, whereby the reference measurement data of all segments then implicitly has a comparable contrast to each other.

For the recording of reference measurement data for a DPG algorithm with a multi-shot EPI recording technique a so-called FLEET technique (FLEET: “fast low-angle excitation echo-planar technique”) can also be used, as is described for example in the article by Polimeni et al. “Reducing Sensitivity Losses Due to Respiration and Motion in Accelerated Echo Planar Imaging by Reordering the Autocalibration Data Acquisition”, Magn. Reson. Med. 75, pp. 665-679, 2016, and in which the reference measurement data of the individual segments is recorded in a short time sequence. In this case the flip angle of the respective excitation varies between the various segments, in order to guarantee that they have a similar contrast to one another.

A recording of reference measurement data for a DPG algorithm already demands a not insignificant amount of time in each case. If further reference measurement data, for a SMS technique for example, for the separation of measurement data recorded collapsed for a number of slices into measurement data of the individual slices, is to be recorded, the overall time needed for recording all reference measurement data is further increased. Between recordings of different types of reference measurement data, it is moreover often necessary to employ further time-consuming, so-called dummy recordings, during which no data is recorded, in order for example to balance out steady-state effects.

FIG. 1 shows a schematic example of a sequence of an EPI SMS measurement with preceding recording of all necessary reference measurement data. For example, it could involve a measurement with an SMS factor of 4 (for example four slices are recorded simultaneously in each case) and a GRAPPA acceleration factor of 2 (i.e. each second k-space row is recorded for example) and 64 slices to be recorded overall.

In this example, a recording by means of a FLEET technique for example, of reference measurement data Rdpg for a DPG algorithm used already takes a time Tdpg, which can amount to around 25 seconds for example. In this case, for each slice to be recorded, reference measurement data Rdpg can be recorded in each case in two segments in two polarization directions of the readout gradient in each case.

The recording of the reference measurement data Rdpg is followed in the example shown by a dummy scan Dsms, e.g. for preparation of a subsequent desired steady state, which in its turn is followed by a recording of reference measurement data Rsms for determination of sensitivity data for separation of measurement data recorded collapsed by means of an SMS technique from a number of slices into measurement data of the individual slices. Such a dummy scan Dsms before a recording of the reference measurement data Rsms is necessary for example when a repetition time TR (Rdpg) of the recording of the reference measurement data Rdpg for the DPG algorithm differs from a repetition time TR (Rsms) of the recording of the reference measurement data for the separation of measurement data recorded collapsed, which without the dummy scan Dsms would lead to undesired steady-state effects, and which is the case as a rule when FLEET is used for the recording of reference measurement data Rpdg. Thus, for the recording of the reference measurement data Rsms for the separation of measurement data recorded collapsed, in the example shown, a time Tsms is to be applied, which can amount to around 11 seconds for example.

Before a recording of measurement data B1 for a first tuple consisting of N (for example N=4) slices by means of the SMS technique used, to prepare for a steady state required for the recording B1 of the measurement data, further, for example two, dummy scans D1, D2 can be applied, which comprise RF pulses that correspond to those during the following recording of measurement data. The recording B1 of the measurement data for the first tuple is followed by all further, for example 15, recordings of measurement data of the other tuples to be recorded of the slices, for example 64 to be recorded overall. A recording of measurement data lasts about 3 seconds here for example, so that the recording of the measurement data in the said example would last 16*3 seconds=48 seconds. The times to be applied for the recording of the reference measurement data Rdpg und Rsms reduce the reduction of the of the overall measurement time in the duration of the actual measurement time of the actual acceleration techniques applied in the recording of the measurement data (in the example SMS and GRAPPA). The time Tsms to be applied for the assumed duration of 11 seconds for the (preparation and) recording of the reference measurement data Rsms already carries weight here.

The underlying object of the disclosure is to make possible a faster and/or better recording of all reference measurement data required for an SMS DP measurement, for example as regards the signal-to-noise ratio (SNR).

The object is achieved by a method for separation of measurement data of an examination object, which is recorded simultaneously as collapsed from a plurality of slices of the examination object and using an in-plane acceleration technique with an undersampled sampling pattern of the k-space corresponding to the acceleration technique by means of a magnetic resonance technique, into single-slice measurement data, by a magnetic resonance system, by a computer program, and also by an electronically-readable data medium, each being as described herein as well as in the claims.

A method for separation of measurement data of an examination object, which is recorded simultaneously by means of magnetic resonance technology as collapsed from a plurality of slices of the examination object and using an in-plane acceleration technique, with an undersampled sampling pattern of the k-space corresponding to the acceleration technique, into individual slice measurement data, comprises the steps:
recording of reference measurement data in at least two segments in such a way that overall a complete set of reference measurement data in accordance with Nyquist is present and that a sampling pattern used in the recording of the reference measurement data within a segment corresponds to an acceleration factor to which the sampling pattern of the measurement data recorded collapsed also corresponds,
recording of the measurement data recorded collapsed,
creation of separation data on the basis of reference measurement data recorded in at least one of the at least two segments,
separation of the measurement data recorded collapsed into single slice measurement data using the created separation data.

Although reference measurement data for a reconstruction of missing k-space data in measurement data recorded by means of an in-plane technique samples the k-space at least in a central area completely in accordance with Nyquist, and, by contrast with this, reference measurement data for later separation of collapsed recording measurement data is recorded with a sampling pattern corresponding with the following recording of measurement data by means of the SMS technique used, e.g. with an in-plane acceleration corresponding with the following recording of measurement data by means of an SMS technique used, reference measurement data for a reconstruction of missing k-space data in measurement data recorded by means of an in-plane technique can be recorded in segments, as proposed in accordance with the embodiments herein.

Through a recording of reference measurement data in segments with a sampling pattern that corresponds to an (in-plane) acceleration factor, to which a sampling pattern used in a recording of measurement data recorded collapsed of a number of slices also corresponds, a further recording of reference measurement data for a separation of the measurement data recorded collapsed can be omitted, whereby an overall time otherwise needed for the recording of the reference measurement data needed is reduced. Furthermore with reference measurement data recorded in accordance with the disclosure for a reconstruction of missing k-space data in measurement data recorded by means of an in-plane technique, a quality of a separation of the measurement data recorded collapsed for a plurality of slices can be enhanced.

A magnetic resonance system comprises a magnet unit, a gradient unit, a radio-frequency unit, and a control facility with a reference measurement data unit embodied for carrying out the method.

A computer program implements a method on a control facility when it is executed on the control facility. For example, the computer program comprises commands that, when the program is executed by the control facility, for example a control facility of a magnetic resonance system, causes this control facility to carry out a method. The control facility can be designed in the form of a computer (e.g. a controller, processing circuitry, etc.).

The computer program can also be present here in the form of a computer program product, which is able to be loaded directly into a memory of a control facility, with program code means for carrying out the method when the computer program product is executed in a processing unit of a computer system.

A computer-readable memory medium comprises commands that, when executed by a control facility, for example a control facility of a magnetic resonance system, cause it to carry out the method.

The computer-readable memory medium can be embodied as an electronically readable data medium, which comprises electronically readable control information stored thereon, which comprises at least one computer program and is designed in such a way that, when the data medium is used in a control facility of a magnetic resonance system it carries out the method.

The advantages and versions specified with regard to the method also apply by analogy to the magnetic resonance system, the computer program product, and the electronically readable data medium.

### BRIEF DESCRIPTION OF THE DRAWINGS

Further advantages and details of the present disclosure emerge from the exemplary embodiments described below and also with the aid of the drawings. The examples given do not represent any restriction of the disclosure. In the figures:

FIG. 1 illustrates a schematic example for a sequence of an echo-planar imaging (EPI) simultaneous multi-slice (SMS) measurement with prior recording of all reference measurement data needed, in accordance with one or more embodiments of the present disclosure;

FIG. 2 illustrates a schematic flow diagram of a method, in accordance with one or more embodiments of the present disclosure;

FIGS. 3-4 illustrates examples of segments with which reference measurement data can be recorded with the aid of its sampling pattern in the k-space, in accordance with one or more embodiments of the present disclosure;

FIGS. 5-6 illustrates examples in the k-space for possible combination data sets, which can be combined for segments for the recording of reference measurement data, in accordance with one or more embodiments of the present disclosure; and

FIG. 7 illustrates a schematic diagram of an example magnetic resonance system, in accordance with one or more embodiments of the present disclosure.

### DETAILED DESCRIPTION OF THE DISCLOSURE

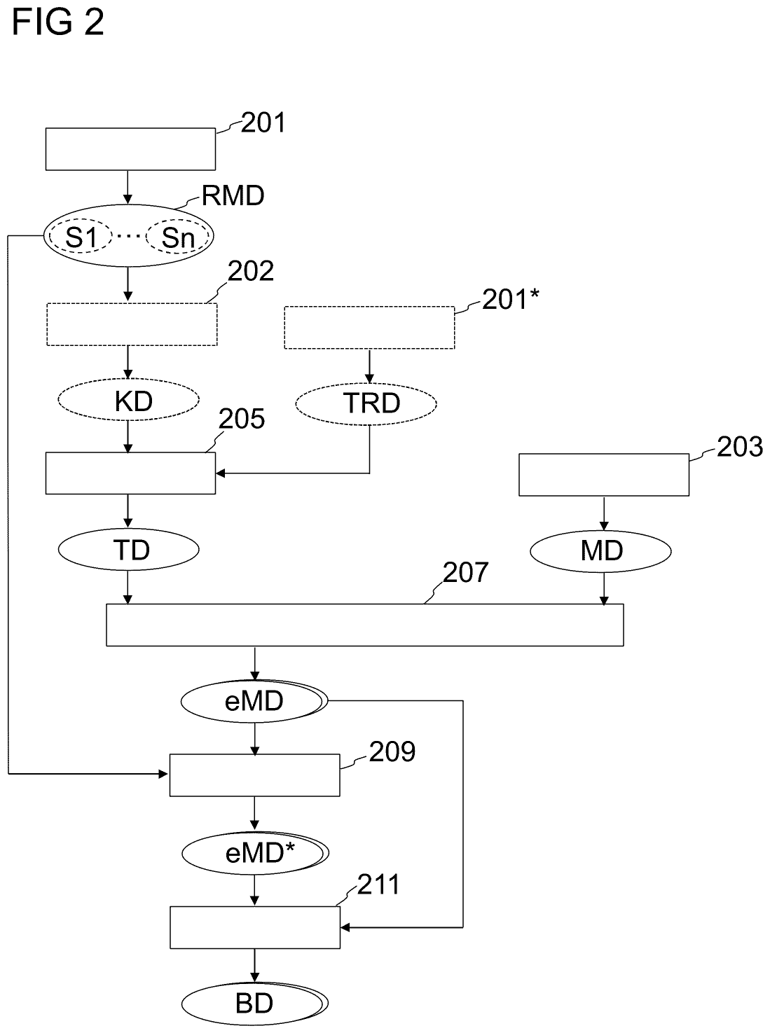

FIG. 2 is a schematic flow diagram of a method for separation of measurement data MD of an examination object, which is recorded as collapsed from a plurality of slices of the examination object simultaneously and by using an in-plane acceleration technique, with an undersampled sampling pattern of the k-space corresponding to the acceleration technique by means of magnetic resonance technology, into single slice measurement data.

In this case, reference measurement data RMD is recorded in at least two segments S1 . . . . Sn in such a way that overall a complete set of reference measurement data in accordance with Nyquist is present, and that a sampling pattern used for the recording of the reference measurement data RMD within a segment S1 . . . . Sn corresponds to an acceleration factor, to which the sampling pattern of the measurement data recorded collapsed (e.g. combined) also corresponds (block 201).

The reference measurement data RMD here can, for example, be reference measurement data for a parallel acceleration technique, for example in-plane GRAPPA. As described above, such reference measurement data is recorded for each desired slice and is complete for each slice at least in a central area of the k-space, i.e. the recorded reference measurement data RMD in all segments used together fills the corresponding k-space completely, and is suitable for the determination of coil sensitivity data from it. Thus, on the basis of such reference measurement data RMD, measurement data not recorded within the framework of a parallel acceleration technique is reconstructed.

In order to divide a recording of such a complete set of reference measurement data into segments in such a way that a sampling pattern used in the recording of the reference measurement data RMD within a segment S1 . . . . Sn corresponds to an acceleration factor, to which the sampling pattern of the measurement data recorded collapsed (e.g. combined) also corresponds, the recording of the reference measurement data can for example simply be divided into a number of segments, which corresponds to an acceleration factor of the recording of the measurement data recorded collapsed, and in each segment a sampling pattern is used that likewise corresponds to the acceleration factor of the sampling pattern of the recording of the measurement data recorded collapsed, wherein however the sampling pattern used samples different k-space data in each segment, so that, by taking the k-space data of the k-space sampled together in the respective segments overall, the sampling is overall complete in accordance with Nyquist.

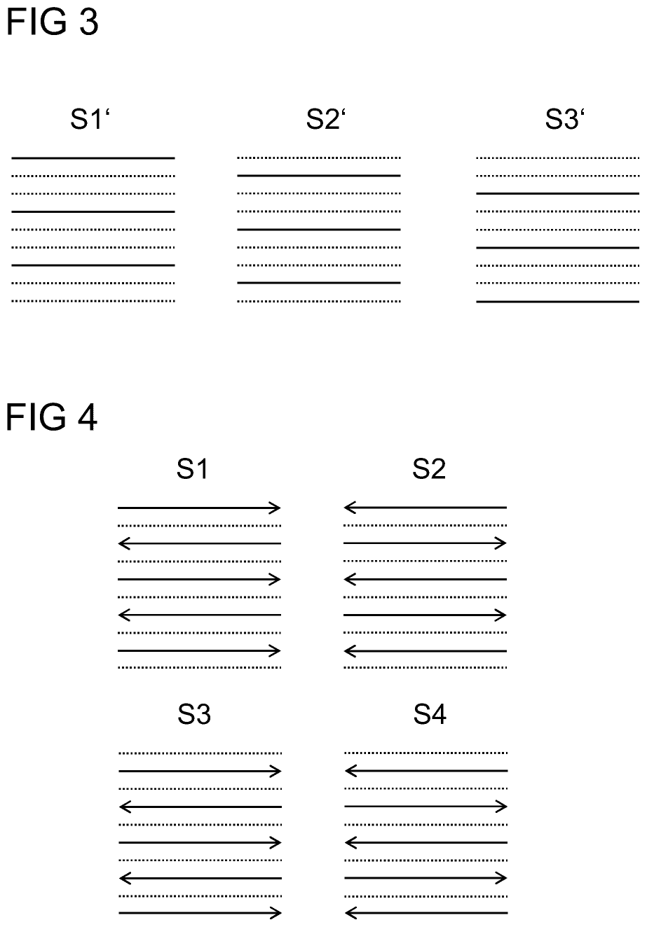

FIG. 3 shows an example of sampling patterns in the k-space for segments S1′, S2′, S3′, along which reference measurement data for a separation of collapsed measurement data recorded with an in-plane acceleration technique, with a sampling pattern that corresponds to an acceleration factor of three, can be recorded.

In the example shown, k-space rows (running in the readout direction), along which in the respective segment S1′, S2′, S3′ reference measurement data RMD is recorded, are shown as solid lines and k-space rows, along which in the respective segment S1′, S2′, S3′ no reference measurement data RMD is recorded, are shown as dotted lines. As can be seen, in accordance with the sampling pattern in the example shown in each segment S1′, S2′, S3′, only every third k-space row is sampled in each case, i.e. reference measurement data is only recorded along every third k-space row, wherein the sampled k-space rows permutate in the segments S1′, S2′, S3′ in such a way that overall each k-space row of the desired k-space is sampled once, so that overall a complete set of reference measurement data is present. The sampling patterns thus correspond here to an acceleration factor of three (PAT=3). The recording of the reference measurement data RMD in the segments S1′, S2′, S3′ is undertaken for each slice recorded in the measurement data MD to be separated and can be carried out in any suitable manner, e.g. using known techniques, with a selected recording technique.

For other acceleration factors in the recording of the measurement data recorded collapsed to be separated the procedure is similar.

The measurement data recorded collapsed can be recorded by means of an EPI recording technique. An EPI recording technique has the above-mentioned advantages and is readily used for example for a diffusion imaging. For instance, for measurement data MD to be separated recorded by means of an EPI recording technique, the reference measurement data can be reference measurement data for a Dual-Polarity GRAPPA (DPG) technique, since with this, as already explained above, ghost artifacts can be removed or at least ameliorated.

As likewise already described above, such reference measurement data for DPG techniques is to be recorded along the k-space rows of the desired k-space as with parallel acceleration techniques completely in accordance with Nyquist, here however additionally also for both readout directions.

FIG. 4 shows an example of sampling patterns in the k-space for segments S1, S2, S3, S4, along which reference measurement data can be recorded for a separation of measurement data recorded collapsed with an EPI-recording technique and with an in-plane acceleration technique, with a sampling pattern that corresponds to an acceleration factor of two.

In the example shown, k-space rows along which reference measurement data RMD is recorded in the respective segment S1, S2, S3, S4, are shown as solid arrows (in the respective readout direction) and k-space rows, along which no reference measurement data RMD is recorded in the respective segment S1, S2, S3, S4, are shown as dotted lines. As can be seen, in accordance with the sampling pattern in the example shown in each segment S1, S2, S3, S4 only every second k-space row is sampled in each case, i.e. reference measurement data is only recorded along every second k-space row. In this case, in segments S1 and S2, and also in segments S3 and S4, the same k-space data is sampled in each case, but in a different readout direction however. The sampled k-space rows each permutate in the segments S1 and S3, and also in the segments S2 and S4, in such a way that overall each k-space row of the desired k-space is sampled once in each readout direction, so that overall one complete set of reference measurement data is present for each readout direction. The sampling patterns here thus correspond to an acceleration factor of two (PAT=2). The recording of the reference measurement data RMD in the segments S1, S2, S3, S4 is undertaken for each slice recorded in the measurement data MD to be separated and can, in a manner known per se, be carried out with a chosen recording technique for DPG techniques.

The procedure can be similar for other acceleration factors in the recording of the measurement data recorded collapsed to be separated.

Measurement data MD recorded collapsed (e.g. combined) to be separated is recorded (block 203). The recording of the measurement data MD recorded collapsed is undertaken directly for example following on from the recording of the reference measurement data RMD and can be undertaken by means of a known slice multiplexing method while using an in-plane acceleration technique, such as (in-plane) GRAPPA for example, with a known recording technique, for example an SMS EPI recording technique.

On the basis of reference measurement data recorded in at least one of the at least two segments, separation data TD is created (block 205).

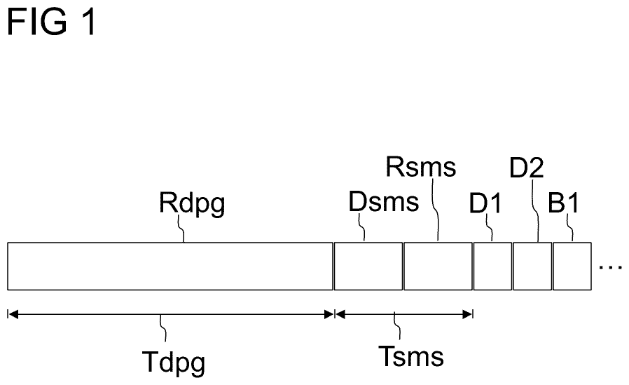

In a simple case, the separation data TD is based on the reference measurement data RMD of one of the at least two segments in which the reference measurement data has been recorded. By the choice of the sampling pattern in the segments of the recording of the reference measurement data in such a way that these correspond to an acceleration factor, which also corresponds to a sampling pattern used in the recording of the measurement data MD to be separated, the effective echo distance during the recording of a segment to reference measurement data is equal to the effective echo distance of the recording of the measurement data recorded collapsed MD. Thus, each segment also already corresponds to a usual, previously-separately recorded, set of reference measurement data Rsms (cf. FIG. 1), and is thus suitable for creating separation data TD in a known manner. For example, the separation data TD can be based on the reference measurement data of one of the segments S1′, S2′, S3′ of FIG. 3 for a recording of the measurement data recorded collapsed MD with an acceleration factor (PAT=3) or, for a recording of the measurement data recorded collapsed MD with an acceleration factor (PAT=4), on one of the segments S1, S2, S3, S4. The separate recording of reference measurement data Rsms can thus be dispensed with.

It is also conceivable for the separation data TD to be based on reference measurement data RMD of at least two of the segments in which the reference measurement data RMD has been recorded. Through the thus higher number of recorded reference measurement data the SNR is increased for example. Furthermore, such an inclusion of more recorded reference measurement data RMD than is recorded in a usual recording of reference measurement data Rsms, can then especially bring a perceptible improvement of the separation data TD with it, when the otherwise usual recording of reference measurement data Rsms only comprises reference measurement data along fewer k-space rows or, when measurement data is recorded collapsed from a large number of slices (for example >4 or >8) simultaneously. This applies for example when separation data TD, in the form of slice-GRAPPA kernels for example, is calculated separately for odd and even k-space rows (as is described in the article by Setsompop et al., “Improving diffusion MRI using simultaneous multi-slice echo planar imaging” NeuroImage 63: pp. 569-580, 2012, in particular with regard to the imaging 2F there) and therefore the effective number of the k-space rows along which reference measurement data RMD is recorded is moved for each slice GRAPPA kernel.

In this case, reference measurement data of the at least two segments can be combined for example in such a way to a combination data set KD that a sampling pattern of the combination data set KD continues to correspond to the acceleration factor to which the sampling pattern of the measurement data recorded collapsed also corresponds (block 202). The separation data TD can then be created on the basis of the combination data set KD.

With such a combination of segments, the procedure can for example be similar to the method described in DE102017209988B3.

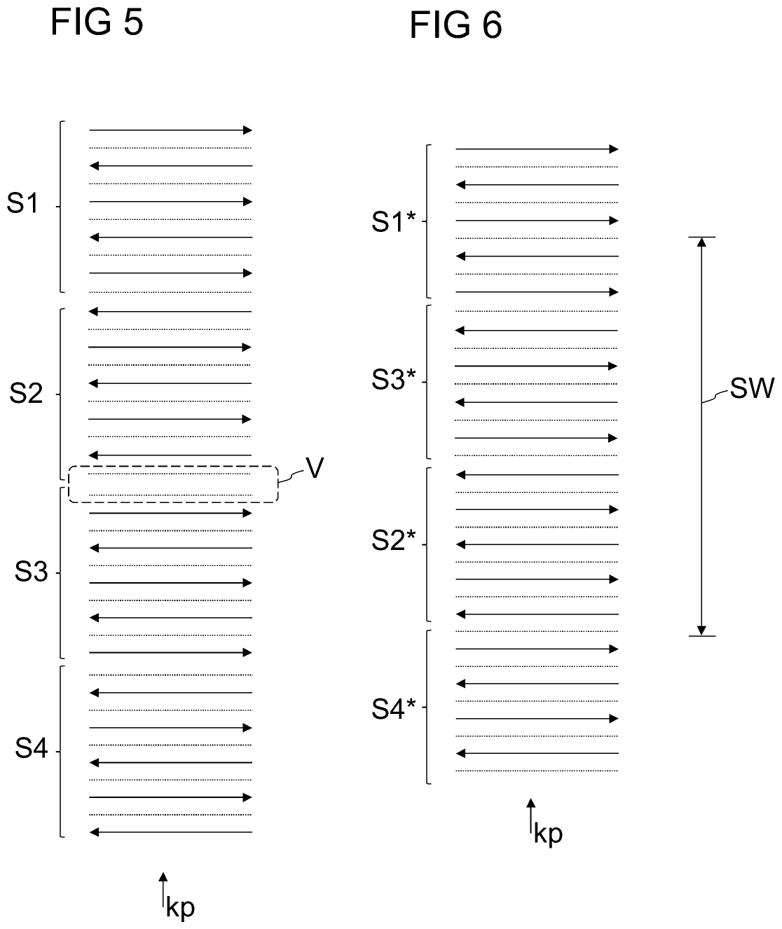

FIG. 5 shows an example of a possible combination data set in the k-space, as could be combined from reference measurement data of the segments S1, S2, S3, S4 of FIG. 4. To this end, sampling patterns of the segments S1, S2, S3, S4 are added to one another (in phase coding direction kp) in such a way that the k-space rows of the segments S1, S2, S3, S4 are parallel and in the kp direction with a distance corresponding to the sampling pattern, lie above one another, whereby the k-space of the combination data set KD is extended in the phase encoding direction.

Care should be taken in the combination of segments of the reference measurement data RMD that the sampling pattern is basically retained, so that this continues to correspond to the acceleration factor to which the sampling pattern of the measurement data recorded collapsed also corresponds. In this case, particular attention is to be paid to the interfaces between the segments, which must be chosen skilfully and/or manipulated accordingly, so that the sampling pattern is retained as desired.

In the example shown in FIG. 5 with an even number (here 10) of k-space rows per segment, the segments cannot be joined to one another without further manipulation without the sampling pattern being disturbed. In the case, shown an interface V occurs between two segments at which the sampling pattern is disturbed.

In order to remove this disturbance, with the combination of segments of the reference measurement data RMD, a subset of the reference measurement data RMD of one of the combined segments can be discarded, e.g. in such a way that the desired sampling pattern is retained. In the example of FIG. 5, either the last k-space row of segment S2 or the first k-space row of segment S3 could be discarded here at the interface V, wherein the position of the segments S1 and S2 can be adjusted in relation to the position of segments S3 and S4 in the kp direction according to the desired sampling pattern.

As an alternative, in the combination of segments of the reference measurement data RMD, reference measurement data RMD of various segments, e.g. reference measurement data in edge areas of the segments and thus at possible interfaces between the segments, can be calculated along with one another in such a way that the desired sampling pattern is retained. In the example of FIG. 5 the last k-space row of segment S2 could be calculated here with the k-space row of segment S3, i.e. at the interface V, for example averaged, and shifted at the same position in the kp direction.

Furthermore, in the combination of segments of the reference measurement data RMD, additional “empty” k-space rows, along which no reference measurement data RMD is recorded can be inserted an interfaces between segments, in order in this way to compensate for possible disturbances of the desired sampling pattern, so that the desired sampling pattern is retained.

FIG. 6 shows an example in the k-space of a possible combination data set, as could be combined from reference measurement data of segments S1*, S2*, S3*, S4*. The segments S1*, S2*, S3*, S4* each have an odd number of k-space rows, so that here, without any further manipulation (as shown) the segments S1*, S2*, S3*, S4* can be successfully combined in such a way that the desired sampling pattern is also retained at the interfaces between the segments S1*, S2*, S3*, S4*.

It is further conceivable for the separation data TD to be based on reference measurement data RMD, which is defined by means of a sliding window technique, which is applied to a combination data set KD. In this way, not all reference measurement data RMD of the combined segments are used as the basis for the separation data TD but only a selected part of said data.

There is a sliding window SW by way of example in FIG. 5, that can be shifted in the kp direction to a desired position to select the k-space rows to be used, along which the reference measurement data RMD to be used as a basis for the separation data TD has been recorded.

The examples of FIGS. 5 and 6 show combination data sets combined from segments of a recording of reference measurement data for a DPG technique. Similarly, combination data sets can also be combined from segments of a recording of reference measurement data for a parallel acceleration technique, wherein as a rule a readout direction used does not have to be noted, but wherein attention should still be paid to possible manipulations of the reference measurement data at the interfaces of the segments. For example, the segments S1′, S2′, S3′ of FIG. 3, in a similar way to the procedure described above, could be arranged above one another and manipulated in order to form a combination data set.

It is furthermore conceivable for separation reference measurement data TRD to be recorded for a separation of the measurement data recorded collapsed MD into single-slice measurement data eMD in addition to the reference measurement data RMD (block 201*). In this case, in a known way, for example as per the process for the reference measurement data Rsms from FIG. 1. The separation data TD can then also be based on the recorded separation reference measurement data TRD. In this way, although the time (for example the time Tsms in FIG. 1) needed for the recording of the separation reference measurement data TRD is not saved, the database on which the separation data TD is determined and the SNR are increased, which can increase the quality of the separation data TD.

The creation of the separation data TD here can comprise an averaging of reference measurement data RMD with separation reference measurement data TRD and/or a comparison of the reference measurement data RMD with the separation reference measurement data TRD regards as artifacts contained in the respective data can be included, based on the result of which it can be chosen which data of the reference measurement data RMD and/or of the separation reference measurement data TRD are used in the creation of the separation data TD, whereby for example motion artifacts, which can be caused for example by a breathing movement, can be taken into account.

The measurement data MD recorded collapsed and simultaneously from a number of slices recorded is separated using the separation data TD created into single-slice measurement data eMD of the individual simultaneously recorded slices (block 207). The separation of the measurement data recorded collapsed MD into single-slice measurement data eMD can be undertaken for example in accordance with a slice GRAPPA method.

Using the reference measurement data RMD recorded (overall entirely in accordance with Nyquist), completed single-slice measurement data eMD* can furthermore be created, in that in the single-slice measurement data eMD (on account of the in-plane acceleration technique used for the recording of the measurement data recorded collapsed MD) missing k-space data can be reconstructed (block 209). The method here can be in the manner basically known, for example in accordance with a GRAPPA technique.

The creation of the separation data TD here can for example comprise an averaging of reference measurement data RMD with separation reference measurement data TRD and/or a comparison of the reference measurement data RMD with the separation reference measurement data TRD as regards artifacts contained in the respective data can be included, based on the result of which it can be chosen which data of the reference measurement data RMD and/or of the separation reference measurement data TRD are used in the creation of the separation data TD, whereby for example motion artifacts, which can be caused for example by a breathing movement, can be taken into account.

Similarly to the creation of separation data TD, provided separation reference measurement data TRD has been recorded, with the completion of the single-slice measurement data eMD to completed single-slice measurement data eMD*, an averaging of reference measurement data RMD with separation reference measurement data TRD and/or a comparison of reference measurement data RMD with the separation reference measurement data TRD as regards artifacts contained in the respective data can be included, based on the result of which it can be chosen which data of the reference measurement data RMD and/or of the separation reference measurement data TRD are used in the creation of the separation data TD, whereby for example motion artifacts, which can be caused for example by a breathing movement, can be taken into account.

From completed single-slice measurement data eMD* and/or, for example using at least one correspondingly trained function, image data BD of the respective slices can be reconstructed in the conventional manner from the single-slice measurement data cMD (block 211).

With the method a recording of separation reference measurement data TRD can thus be omitted, which overall saves recording time needed. In addition, or as an alternative, the quality of the separation data can be greatly improved by an inclusion of more reference measurement data than otherwise usual and/or an inclusion of still recorded separation reference measurement data TRD.

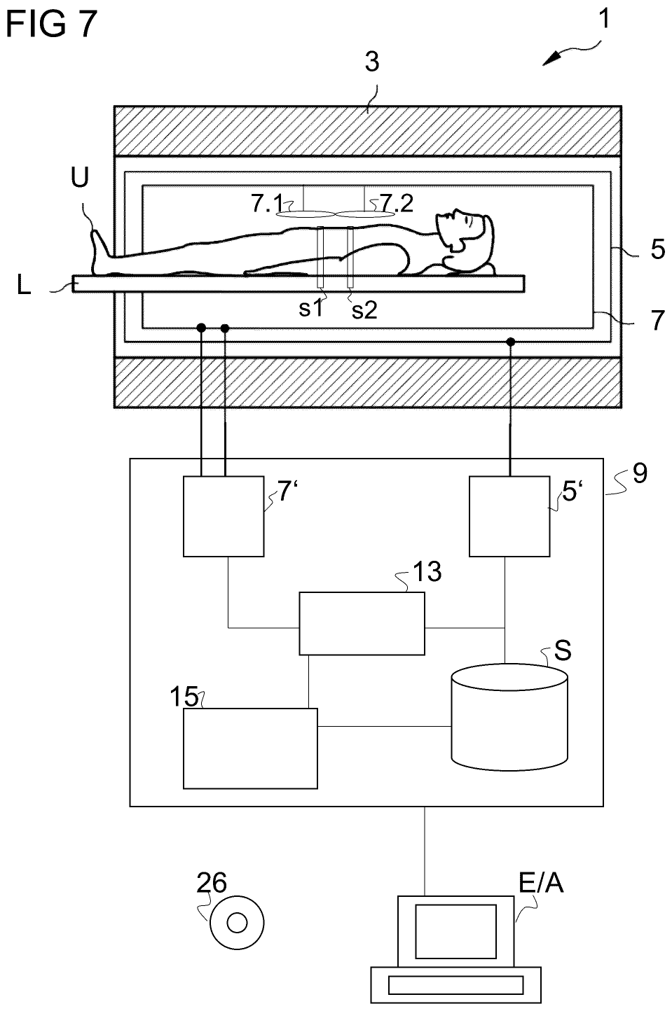

FIG. 7 shows a schematic of an example magnetic resonance system 1. This comprises a magnet unit 3 for generating the basic magnetic field, a gradient unit 5 for generating of the gradient fields, a radio-frequency (RF) unit 7 for emission and for receipt of RF signals, and a control facility 9 (e.g. a controller, processing circuitry, a computer, etc.) embodied for carrying out any of the methods as discussed herein.

These part units of the magnetic resonance system 1 are only shown as rough schematics in FIG. 7. The RF unit 7 may, for instance, comprise a number of subunits, for example of a number of coils such as the schematically shown coils 7.1 und 7.2 or more coils, which can be designed just for transmission of RF signals or just for receipt of the triggered RF signals, or both.

For examination of an examination object U, for example of a patient or also of a phantom, this can be introduced onto a couch L into the magnetic resonance system 1 in its measurement volume. The schematically shown slices s1 and s2 represent examples of slices of a target volume of the examination object able to be recorded individually or also simultaneously (by means of a slice multiplexing method), from which echo signals are recorded and can be acquired as measurement data.

The control facility 9 is used for control of the magnetic resonance system 1 and may for instance control the gradient unit 5 by means of a gradient controller 5′ und the RF unit 7 by means of a RF transceiver controller 7′. The RF unit 7 can comprise a number of channels here on which signals can be transmitted or received.

The RF unit 7, together with its RF transceiver controller 7′, is responsible for the creation and the emission (transmission) of a RF alternating field for manipulation of the spins in a region to be manipulated (for example in slices S to be measured) of the examination object U. In this case the midfrequency of the radio-frequency alternating field, as referred to as the B1-field is as a general rule adjusted so that it lies close to the resonant frequency of the spins to be manipulated. Deviations of the center frequency from the RF are referred to as off-resonance. For creation of the B1-field currents are applied to the RF coils in the RF unit 7 controlled by means of the RF transceiver controller 7′.

The control facility 9 furthermore comprises a reference measurement data unit 15, with which the recording of reference measurement data as discussed above can be controlled. The control facility 9 is configured overall to carry out any of the method as described herein.

A processing unit 13 comprised by the control facility 9 is configured to carry out all processing operations needed for the measurements and determinations needed. Intermediate results needed or determined here can be stored in a memory unit S of the control facility 9. The units shown here are not to be understood as physically separate units, but merely represent a subdivision into logical units, which however can also be realized in fewer or also in just one single physical unit.

Via an input/output facility E/A of the magnetic resonance system 1 control commands, by a user for example, can be directed to the magnetic resonance system and/or results, such as image data for example, displayed on the control facility 9.

A method described herein can also be present in the form of a computer program, which comprises commands that carry out the method described on a control facility 9. Likewise, a computer-readable memory medium can be present, which comprises commands that, when executed by a control facility 9 of a magnetic resonance system 1, cause said system to carry out the method described.

Independent of the grammatical term usage, individuals with male, female or other gender identities are included within the term.

The various components described herein may be referred to as “units” or a “control facility.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such units and/or control facilities, as applicable and relevant, may alternatively be referred to herein as “circuitry,” “controllers,” “processors,” or “processing circuitry,” or alternatively as noted herein.

What is claimed is:

1. A method for separation of measurement data, comprising:
simultaneously recording, via a magnetic resonance imager, the measurement data for a plurality of slices of an examination object via an in-plane acceleration technique in accordance with an undersampled sampling pattern of k-space, as combined slice measurement data;
recording reference measurement data in at least two segments such that (i) a complete set of reference measurement data is recorded in accordance with satisfaction of a Nyquist condition, and (ii) a sampling pattern used for the recording of the reference measurement data within the at least two segments corresponds to an acceleration factor of a sampling pattern used to record the measurement data;
generating separation data based upon the reference measurement data that is recorded in at least one of the at least two segments;
separating the combined measurement data into single-slice measurement data using the separation data; and
generate image data based upon the single-slice measurement data.

2. The method of claim 1, wherein the reference measurement data comprises reference measurement data for a parallel acceleration technique.

3. The method of claim 2, wherein the parallel acceleration technique comprises an in-plane GeneRalized Autocalibrating Partially Parallel Acquisition (GRAPPA).

4. The method of claim 1, wherein the measurement data is recorded via an echo-planar imaging (EPI) technique, and
wherein the reference measurement data comprises reference measurement data for a dual-polarity GeneRalized Autocalibrating Partially Parallel Acquisition (DPG) technique.

5. The method of claim 1, wherein the separation data is based on reference measurement data of the at least two segments in which the reference measurement data has been recorded.

6. The method of claim 5, wherein reference measurement data of the at least two segments is combined into a combination data set such that a sampling pattern of the combination data set corresponds to a sampling pattern used to record the measurement data, and
wherein the separation data is generated based upon the combination data set.

7. The method of claim 6, wherein during the combining of the at least two segments of the reference measurement data, discarding a subset of the reference measurement data.

8. The method of claim 6, wherein during the combining of the at least two segments of the reference measurement data, generating the reference measurement data based upon a calculation of reference measurement data of edge regions of the at least two segments with respect to one another.

9. The method of claim 8, wherein the calculation of reference measurement data of edge regions of the at least two segments with respect to one another comprises an average of the reference measurement data of the edge regions of the at least two segments.

10. The method of claim 6, wherein the separation data is based on reference measurement data that is defined via a sliding window technique that is applied to the combination data set.

11. The method of claim 1, wherein the separation data is based on the reference measurement data of one of the at least two segments in which the reference measurement data has been recorded.

12. The method of claim 1, further comprising:
recording separation reference measurement data,
wherein the separation data is based upon the recorded separation reference measurement data.

13. The method of claim 12, wherein the generation of the separation data comprises averaging the reference measurement data with the separation reference measurement data.

14. A magnetic resonance system, comprising:
a magnet unit; and
a controller configured to cause the magnetic resonance system to:
simultaneously record measurement data for a plurality of slices of an examination object via an in-plane acceleration technique in accordance with an undersampled sampling pattern of k-space, as combined slice measurement data;
record reference measurement data in at least two segments such that (i) a complete set of reference measurement data is recorded in accordance with satisfaction of a Nyquist condition, and (ii) a sampling pattern used for the recording of the reference measurement data within the at least two segments corresponds to an acceleration factor of a sampling pattern used to record the measurement data;
generate separation data based upon the reference measurement data that is recorded in at least one of the at least two segments;
separate the combined measurement data into single-slice measurement data using the separation data; and
generate image data based upon the single-slice measurement data.

15. A non-transitory computer-readable memory medium having instructions stored thereon that, when executed by one or more processors of a magnetic resonance system, cause the magnetic resonance system to:
simultaneously record measurement data for a plurality of slices of an examination object via an in-plane acceleration technique in accordance with an undersampled sampling pattern of k-space, as combined slice measurement data;
record reference measurement data in at least two segments such that (i) a complete set of reference measurement data is recorded in accordance with satisfaction of a Nyquist condition, and (ii) a sampling pattern used for the recording of the reference measurement data within the at least two segments corresponds to an acceleration factor of a sampling pattern used to record the measurement data;
generate separation data based upon the reference measurement data that is recorded in at least one of the at least two segments;
separate the combined measurement data into single-slice measurement data using the separation data; and
generate image data based upon the single-slice measurement data.
